(19) United States
(12) Patent Application Publication
(10) Pub. No.: US 2026/0323985 A1
(43) Pub. Date: Oct. 15, 2026

(54) A power transistor for a semiconductor device

(71) Applicants: Consiglio Nazionale delle Ricerche, Roma RM (IT); STLab S.r.l., Catania CT (IT)

(72) Inventors: Massimo CAMARDA, Catania CT (IT); Francesco LA VIA, Roma RM (IT)

(21) Appl. No.: 19/485,589

(22) PCT Filed: May 17, 2024
(86) PCT No.: PCT/IB2024/054804

§ 371 Date: Nov. 18, 2025

(30) Foreign Application Priority Data
May 19, 2023 (IT) 102023000010203

(51) Int. Cl. H10D 30/60; H10D 30/01; H10D 62/10; H10D 62/17; H10D 62/832; H10P 50/00; H10P 50/24

(52) U.S. Cl. CPC H10D 30/611; H10D 30/023; H10D 62/124; H10D 62/292; H10D 62/8325; H10P 50/242; H10P 50/692; H10P 50/695

(57) ABSTRACT

A power transistor for a semiconductor device, comprising: a support layer made of Silicon Carbide with a bottom surface, at least one epitaxial layer grown on its top and having a top surface opposite to the bottom surface along a first direction (X-X); a drain arranged at least partially on the bottom surface; a plurality of gates and sources alternately arranged on the top surface and spaced apart from each other along a second direction (Y-Y); a plurality of inversion channel regions generated within the thickness of the epitaxial layer for transporting charges, each inclined relative to the top surface by an inclination angle, ranging from 1° to 5°, substantially equal to the crystal basal planes (200) inclination angle (201), and each comprising a step free-area (111) and being devoid of accumulation areas (112).

### TECHNICAL FIELD

The present disclosure is related to a power transistor for a semiconductor device, comprising a support layer made of Silicon Carbide (SiC).

### STATE OF THE ART

A power transistor for a semiconductor device is, for example, a specific type of metal-oxide semiconductor field-effect transistor (MOSFET) designed to handle significant power levels.

The structure of such power MOSFETs is generally implemented with a so called VDMOS structure, i.e., a Vertical implanted MOS also called Double-implanted MOS or simply DMOS.

The cross section of a DMOS shows the “verticality” of the device-it can be seen that the source electrode is placed over the drain, resulting in a current mainly vertical when the transistor is in the on-state.

With a vertical structure, the voltage rating of the transistor is a function of the doping and thickness of the N epitaxial layer, while the current rating is a function of the channel width. This makes it possible for the transistor to sustain both high blocking voltage and high current within a compact piece of Silicon Carbide (SiC).

Considering the dependence of the characteristics of the prior art power MOSFETs on the substrate and epitaxial layer morphology, documents EP3371654 and JP2009182240 disclose methods for processing or modifying the surface of the substrate in order to increase the channel mobility.

### PROBLEM OF THE PRIOR ART

However, since the characteristics of known power MOSFETs are strictly dependent on the substrate and epitaxial layer morphology, and due to the property changes resulting from substate modification, said power MOSFETs can be challenging to design or manufacture.

For example, the substrate and epitaxial layer morphology can yield variation of the transistor characteristics and ultimately reduce fabrication yield and device quality.

Moreover, it is also known that the substrate and epitaxial layer morphology are strictly related to the specific fabrication process.

In fact, in the case of 4H-Silicon Carbide (4H-SiC) semiconductors, in order to maintain the polytype of the support layer during low-temperature (<1600 °C), chemical vapor deposition (CVD) homoepitaxial growths, the support layer is cut a few degrees (2°-8°) off-axis from the basal plane, i.e., the (0001) plane, promoting a lateral epitaxial growth at the surface steps.

While this step-controlled epitaxial CVD growth results in electronic grade single-polytype epilayers, it also leads to the creation of atomic steps on the top surface of the epitaxial layer, commonly referred to as micro-steps, together with the formation of so-called isolated macro-steps, consisting of bunched micro-steps of several nanometers in height. The final uncontrolled distribution of the micro and macro-steps on the surface will then have effects on the properties of fabricated devices.

In particular, since the thermal oxidation process strongly depends on the surface orientation and on the local surface crystal structure, the described surface morphology will significantly influence the electrical properties of the manufactured MOS devices.

For example, the non-uniformity of the thickness of the oxide will induce surface potential variations and, ultimately, a variation in the MOSFET threshold voltage (Vth).

Apart from the variations in the oxide growth rate, a stepped surface leads to an increased number of interface defects (DIT) as incomplete crystal planes will favor non-ideal oxidations.

Furthermore, the distribution of atomic steps is highly non-uniform leading to large variations of the electronics properties of the fabricated devices, ultimately decreasing the yields and overall characteristics.

Document EP3371654 discloses a method to modify the substrate surface of an existing power MOSFET in order to obtain ex post the channel regions at terraces of the substrate surface. In particular, document EP3371654 defines the terraces of the substrate surface as flat sections oriented more parallel to the averaged surface of the substrate compared to steep sections, which are oriented more parallel to the vector normal of the averaged surface.

Instead, document JP2009182240 discloses a method to generate a plurality of large terraces separated by macro steps so that, statistically, the channel regions will be “mostly” located on the large terraces, leading to lower interface defects (DIT) and better channel mobilities.

The power MOSFETs of above-mentioned methods have, in both cases, terraces in positions not controlled with respect to sources, drain and channel regions (EP3371654) and not reproducible along the fabrication process. As a result, each power MOSFET has different electrical properties from the others. Therefore, these methods are not reliable enough.

In addition, the power MOSFETs of the state of the art do not have an adequate pitch between sources and, as a result, have a sub-optimal current transport in the on-state.

### SCOPE OF THE INVENTION

In this context, the technical object of the present disclosure is to provide a power transistor for a semiconductor device which overcome the drawbacks of the prior art.

Namely, the object of the present disclosure is to provide a power transistor for a semiconductor device that does not limit the performance and the reliability of the semiconductor device incorporating such power transistor.

In addition, the object of the present disclosure is to provide a process for producing a semiconductor device incorporating such improved power transistor.

The specified technical object and the specified aims are substantially achieved by a power transistor comprising the technical characteristics described in one or more of the appended claims.

### ADVANTAGES OF THE INVENTION

The power transistor described allow to obtain a semiconductor device wherein there is a better control of the gate threshold voltage (Vth), an improvement of the oxide thickness uniformity, a reduction of the DIT, which in turn will reduce the Coulomb scattering and improve the channel mobility at low-medium gate voltages, and a reduction of the interface scattering, thus improving the channel mobility at high gate voltages.

Furthermore, the power transistor for a semiconductor device according to the present disclosure shows a well-controlled distribution of terraces and atomic steps, specifically allocated with respect to the channel regions and sources, respectively. This makes it possible to achieve a significantly lower contact resistance in source regions, by accumulations of atomic steps, and a lower resistance of inversion channel regions, by elimination of the atomic steps and creation of single terrace.

Advantageously, the process according to the present disclosure allows to achieve a constant distribution of terraces and atomic steps between different power transistors fabricated, thus exhibiting a high reliability of the process itself.

### BRIEF DESCRIPTION OF THE DRAWINGS

Further characteristics and advantages of the present disclosure will appear more clearly from the indicative, and therefore non-limiting, description of a preferred but not exclusive embodiment of a power transistor for a semiconductor device as illustrated in the enclosed drawings in which:

FIG. 1 is a schematic view of a power transistor for a semiconductor device according to the present disclosure;

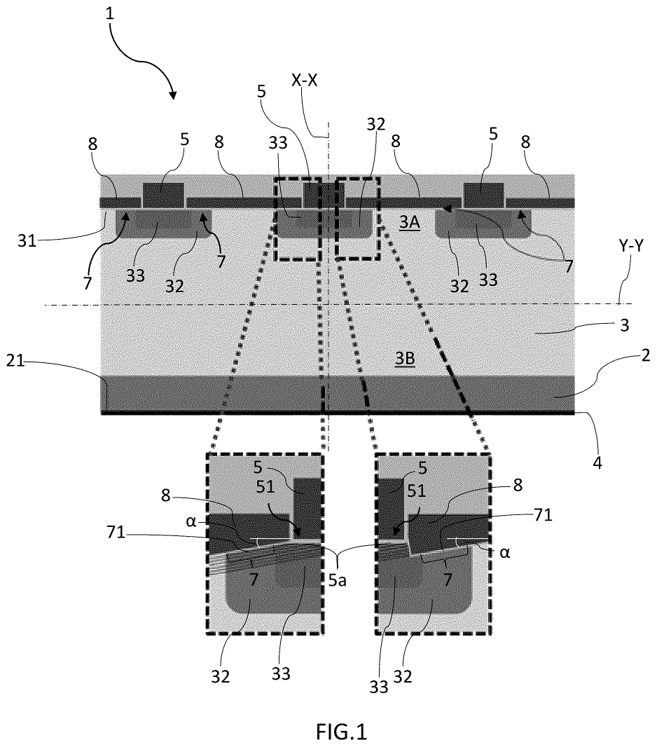

FIG. 2a is a first part of a schematic view of the different structures obtained during a process for producing a semiconductor device incorporating the power transistor of FIG. 1;

FIG. 2b is a second part of the schematic view of the different structures obtained during the process for producing a semiconductor device incorporating the power transistor of FIG. 1;

FIG. 3 is a schematic view of a detail of the power transistor for a semiconductor device according to FIG. 1.

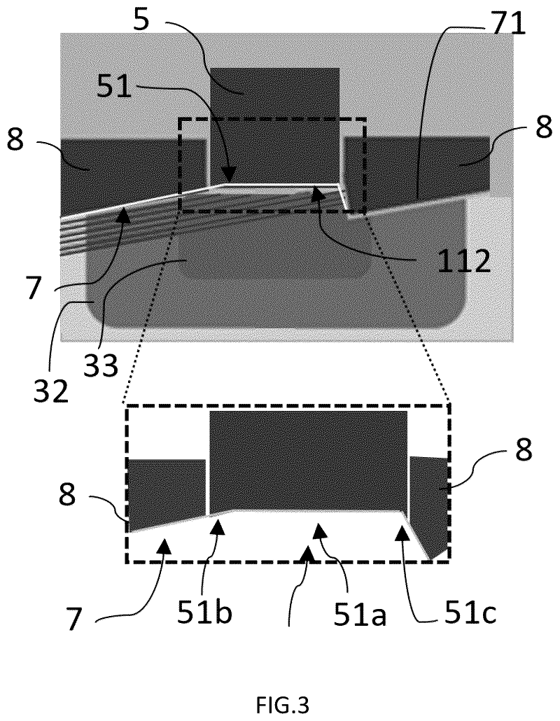

### DETAILED DESCRIPTION

With reference to the attached figures, numeral 1 designates a power transistor for a semiconductor device. For example, the power transistor 1 is a MOSFET, particularly a Silicon Carbide VDMOS, or an IGBT.

The power transistor 1 comprises a support layer 2 made of Silicon Carbide and having a bottom surface 21.

Preferably, the support layer 2 is a high quality single crystalline 4H Silicon Carbide wafer with either medium-high conductivity (<20 mΩcm, based on controlled contamination with n-type impurities) or semi-insulating (>1 MΩ·cm) properties.

Still preferably, the support layer 2 is obtained by PVD growth processes.

Moreover, the power transistor 1 comprises at least one epitaxial layer 3 grown on top of the support layer 2 and having a top surface 31 opposite to the bottom surface 21 of the support layer 2 with respect to a first direction X-X.

It should be noted that the top surface 31 comprises a faceted morphology, which has separated regions with different surface orientations. An example of a faceted morphology is an undulated surface. More specifically, the top surface 31 comprises atomic steps and terraces. The atomic steps are referred to as micro steps and nano steps, which form macro steps consisting of micro steps and nano steps grouped in clusters of several nanometers in height. The terraces are flat sections of the top surface 31 which are oriented more parallel to the averaged surface of the top surface 31 compared to steep sections, related to atomic steps, which are oriented more parallel to the vector normal of the averaged top surface 31.

The distribution of terraces and atomic steps on the top surface 31 will be better described hereinafter.

Preferably, the power transistor 1 comprises a plurality of epitaxial layers 3 grown on top of the support layer 2. Said plurality of epitaxial layers 3 comprises a top most epitaxial layer 3A and a lower epitaxial layer 3B. The lower epitaxial layer 3B is in contact with the support layer 2, while the top most epitaxial layer 3A is grown on top of the lower epitaxial layer 3B.

In case of more than two epitaxial layers 3, the plurality of epitaxial layers 3 comprises intermediate epitaxial layers interposed between the lower epitaxial layer 3B and the top most epitaxial layer 3A.

In case of the plurality of epitaxial layers 3, the top surface 31 is defined on the top most epitaxial layer 3A.

Preferably, the thickness of the at least one epitaxial layer 3 along the first direction X-X is smaller than the thickness of the support layer 2 along the first direction X-X.

In addition, the power transistor 1 comprises a drain 4 arranged at least partially on the bottom surface 21 of the support layer 2.

According to a preferred embodiment, the drain 4 directly contacts at least a portion of the at least one epitaxial layer 3.

In an alternative embodiment, the drain 4 directly contacts the lower epitaxial layer 3B since at least a portion of the support layer 2 is removed.

The power transistor 1 comprises a plurality of gates arranged on the top surface 31 and being spaced apart from each other along a second direction Y-Y transverse to the first direction X-X.

Preferably, the second direction Y-Y is perpendicular to the first direction X-X. In addition, the power transistor 1 comprises a plurality of sources 5 arranged on the top surface 31. Each source 5 is interposed between a couple of gates. Preferably, each source 5 is arranged at a predetermined distance, also known as the pitch, from one or more adjacent sources 5. It should be noted that the pitch between the sources influences the electrical properties of the power transistor 1.

Preferably, each gate is a stack of an insulator (preferentially SiO₂) and some conductive layer on top (a metal or doped polysilicon). Still preferably, each source 5 is a doped SiC region, with on top some conductive layer (some silicide plus e.g., Aluminum). In detail, each source 5 comprises a source region 51 defined by an interface 5a between the conductive layer, e.g., a metal layer, and the SiC region.

According to the disclosure, the interface 5a of each source region 51 could have one or more surfaces 51a, 51b, 51c with different inclination angles with respect to the top surface 31. Further details of the respective inclination angles of the surfaces 51a, 51b, 51c of the interface 5a of source region 51 will be provided hereinafter.

The power transistor 1 comprises a plurality of first implanted regions 32 being formed in the thickness of the at least one epitaxial layer 3.

In case of the plurality of epitaxial layers 3, the first implanted regions 32 are formed, at least in part, in the thickness of the top most epitaxial layer 3A.

Preferably, each first implanted region 32 corresponds to a p-well.

Each source 5 is arranged on the top surface 31 above a respective first implanted region 32. In addition, each gate is arranged on the top surface 31 partially above a respective first implanted region 32.

The power transistor 1 comprises a plurality of second implanted regions 33.

Preferably, each second implanted region 33 corresponds to a n⁺ region.

Each second implanted region 33 is formed at least partially inside a respective first implanted region 32.

Preferably, each second implanted region 33 is formed totally inside the first implanted region 32.

According to the embodiment shown in the attached Figure, each source 5 is arranged on the top surface 31 above a respective second implanted region 33.

The power transistor 1 comprises a plurality of oxide layers 8 arranged on the top surface 31. Each oxide layer 8 is placed between a couple of sources 5.

Each gate is arranged on top of a respective oxide layer 8.

The power transistor 1 comprises a plurality of inversion channel regions 7 being configured to transport charges and being configured to be generated within the thickness of the at least one epitaxial layer 3. As it is per se known to the skilled person, each inversion channel region 7 is generated during the “on-state” of the power transistor 1.

In case of the plurality of epitaxial layers 3, the plurality of inversion channel regions 7 are configured to be generated within the thickness of the top most epitaxial layer 3A.

Each inversion channel region 7 is configured to be generated below and in contact with a respective oxide layer 8. Namely, each inversion channel region 7 has an interface surface 71 in contact with a respective oxide layer 8. Preferably, each inversion channel region 7 is configured to be generated, at least partially, in a respective first implanted region 32.

According to the disclosure, each inversion channel region 7 is inclined with respect to the top surface 31 by an inclination angle α. Namely, the interface surface 71 of each inversion channel region 7 is inclined with respect to the top surface 31 by the inclination angle α. The inclination angle α of each inversion channel region 7 ranges from 1° to 5°.

Preferably, the inclination angle α of each inversion channel region 7 ranges from 3.5° and 4.5°.

Most preferably, the inclination angle α of each inversion channel region 7 is equal to 4°.

As it will be better described hereinafter, the feature of having inversion channel regions 7 inclined with respect to the top surface 31 is obtained by locally dissolving the at least one epitaxial layer 3, to locally align it to the crystal basal planes 200. In fact, the crystal basal planes 200 are inclined with respect to the top surface 31 by a respective inclination angle 201.

According to the disclosure, the inclination angle α of each inversion channel region 7 is substantially equal to the inclination angle 201 of the crystal basal planes 200.

In other words, each inversion channel region 7 is substantially aligned with crystal basal planes 200.

Still according to the disclosure, each inversion channel region 7 comprises a step-free area 111 of the top surface 31. In detail, each step free area 111 can be intended as a single terrace of the top surface 31. In other words, each terrace of the top surface 31 is arranged at a respective inversion channel region 7.

Moreover, each inverse channel region 7 is devoid of accumulation areas 112, and specifically is devoid of atomic steps. In detail, each accumulation area 112 is defined by the accumulation of atomic steps in a specific area of the top surface 31.

In more detail, thanks to the inclination angle α of each inversion channel region 7, specifically ranging between 1° and 5°, it is possible to obtain that the inversion channel regions 7 are locally planarized.

Namely, by implementing each inversion channel region 7 inclined with the inclination angle α, specifically ranging between 1° and 5°, it allows to obtain that the inversion channel regions 7 do not comprise atomic steps. In fact, the local planarization of each inversion channel regions 7 avoids the presence of atomic steps, and preferably of micro steps and nano steps.

Therefore, the inclination of each inversion channel region 7 allows to obtain better performance and reliability of the semiconductor device incorporating the power transistor 1.

As it will be better described hereinafter, in order to obtain a power transistor 1 having the inversion channel regions 7 devoid of atomic steps, the atomic steps must be accumulated in other areas of the top surface 31, and in particular in the accumulation areas 112.

According to the disclosure, the accumulation areas 112, specifically the atomic steps of the top surface 31, are thus arranged at the source region 51 of each source 5. More specifically, both the micro steps and nano steps are arranged at the source region 51 of each source 5.

It should be noted that this accumulation of atomic steps in the source regions 51 makes it possible to obtain a lower contact resistance at each interface 5a between SiC regions and conductive layers of the sources 5.

Furthermore, due to the accumulation of micro and nano steps in the source regions 51, the macro steps are also arranged at the source regions 51 of the sources 5 and thus in the accumulation areas 112 of the top surface 31.

Therefore, each inversion channel region 7 is also free of macro steps.

It should also be noted that the accumulation of atomic steps in the source regions 51 can take in different forms. Specifically, each source region 51 can comprise a regular surface 51a substantially parallel to the averaged top surface 31. In detail, the atomic steps are randomly distributed in the regular surface 51a.

Moreover, each source region 51 can comprise a first inclined surface 51b, corresponding to a terrace, which is free of atomic steps. In detail, the first inclined surface 51b can be arranged in proximity of the adjacent inversion channel region 7. More particularly, the first inclined surface 51b is inclined with respect to the top surface 31 with the same inclination angle α of the adjacent inversion channel region 7.

Furthermore, each source region 51 can comprise a second inclined surface 51c defined by the accumulation of atomic steps, and in particular of one or more macro steps of the top surface 31. In detail, the inclination angle of the second inclined surface 51c with respect to the top surface 31 is greater than the inclination angle of the first inclined surface 51b or than the inclination angle α of the inversion channel regions 7.

It should be noted that in this way there is a constant and substantially uniform distribution and alternation of terraces and atomic steps on the top surface 31. The alternation of terraces and atomic steps is specifically aligned to both the inversion channel regions 7 and sources 5.

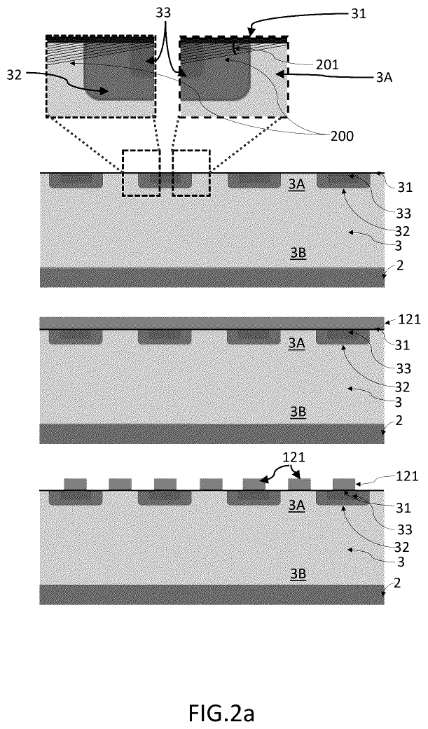

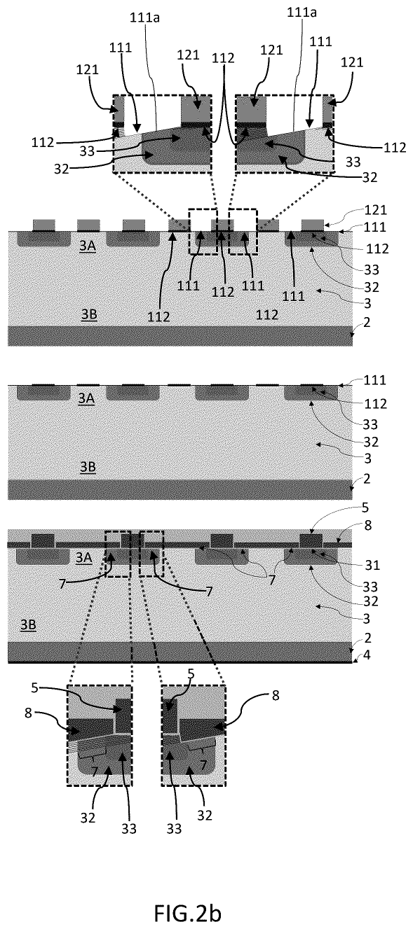

It should also be noted that this constant and substantially uniform distribution of terraces and atomic steps allows to achieve a double effect: the lack of atomic steps in the inversion channel regions 7, as can be seen in FIG. 2b, which would otherwise deteriorate the electrical properties of these regions, and the accumulation of the atomic steps in the source regions 51 of the sources 5, as shown in FIG. 2b, where the atomic steps instead improve the electrical properties by reducing the contact resistance.

The effects of avoiding deterioration of the electrical properties of inversion channel regions and of improving the electrical properties by reducing the contact resistance in source regions can also be obtained for a transistor having the above-described technical features in only a fraction of the total number of inversion channel regions 7 and/or source regions 51. Indeed, it is clear that the transistor described in the present description is to be interpreted as having the same advantages in the two cases mentioned.

These advantages are technically demonstrable by means of specific technical tests both for transistors having all inversion channel regions and source regions according to the present disclosure, and for transistors having only a fraction of inversion channel regions and source regions thus formed.

It should be noted that all the values of the inclination angle α of each inversion channel region 7 defined above should be considered together with the intrinsic measurement error, known to the skilled person. In particular, the intrinsic measurement error is no more than 10% of the values of the inclination angle α of each inversion channel region 7 defined above.

In case of the plurality of epitaxial layers 3, the feature of having inversion channel regions 7 inclined with respect to the top surface 31 is obtained by locally dissolving the top most epitaxial layer 3A to locally align to the crystal basal planes 200.

It should be noted that the inclination angle α of each inversion channel region 7 can be measured by first using a Scanning Electron Microscope (SEM) and then using a Transmission Electron Microscope (TEM).

More in details, measurements start by performing cross-section SEM of the power transistor 1 to allow identification of the differently doped regions of the power transistor 1, due to the different electrons emission rates associated with regions with different doping (i.e., different surface potentials). From this analysis it is possible to identify the inversion channel regions 7, i.e., confirm the location of the inversion channel regions 7 with respect to the gates, sources 5 and oxide layers 8.

Then, the power transistor 1 can be seen with TEM, initially at low magnification measurement, e.g., more than ten microns total field of view, to identify, through the location of gates, sources 5 and oxide layers 8 as observed at SEM, the exact locations of the inversion channel regions 7.

It should be noted that the TEM measurement must be performed in cross-section, i.e., with the probing electron beam directed orthogonal to the charged carriers flow during on-state operations of the power transistor 1.

Afterwards, using the same TEM configuration, it is performed a high-resolution analysis, i.e., an atomic-level analysis, of the inversion channel regions 7 to identify the SiO₂/SiC interface surface 71 of each inversion channel regions 7.

Finally, the inclination angle α between the interface surface 71 of each inversion channel regions 7 and the top surface 31 is determined.

A process for producing a semiconductor device incorporating the power transistor 1 described is a further object of the present disclosure.

Said process comprises the step of providing a support layer 2 made of Silicon Carbide, preferably 4H Silicon Carbide, and the step of forming on top of the support layer 2 at least one epitaxial layer 3 having a top surface 31.

Preferably, the step of forming on top of the support layer 2 at least one epitaxial layer 3 comprises forming on top of the support layer 2 a plurality of epitaxial layers 3 comprising a lower epitaxial layer 3B, a top most epitaxial layer 3A and, optionally, intermediate epitaxial layers interposed between the lower epitaxial layer 3B and the top most epitaxial layer 3A. In case of forming the plurality of epitaxial layers 3, the top surface 31 is defined on the top most epitaxial layer 3A.

It should be noted that the top surface 31 is initially composed by an uncontrolled distribution of steps and terraces due to the misorientation of the support layer 2 made of Silicon Carbide.

Then, the process comprises the step of depositing a masking layer 121 on the top surface 31.

After depositing the masking layer 121, the process comprises the step of removing the masking layer 121 in specific areas of the top surface 31. Said specific areas corresponds, at least partially, to the inversion channel regions 7 of the power transistor 1 to be fabricated.

After removing the masking layer 121 in specific areas the process comprises the step of performing a slow etching process allowing for the generations of step-free areas 111, located at the specific areas of the top surface 31, and accumulation areas 112, adjacent to the step-free areas 111. Preferably, each step-free area 111 is interposed between a couple of accumulation areas 112.

It should be noted that the step-free areas 111 correspond, at least partially, to the inversion channel regions 7 of the power transistor 1 to be fabricated. Moreover, said accumulation areas 112 correspond, at least partially, to the source regions 51 of the sources 5 of the power transistor 1 to be fabricated.

It should also be noted that in the step-free areas 111 the steps are removed, while in the accumulation areas 112 the steps will accumulate.

In fact, the average direction of the top surface 31 cannot be modified, in particular the average sum of local changes of angles on the top surface 31 must be null. More specifically, the local changes obtained on the top surface 31 by the slow etching in order to obtain the step-free areas must be offset by the accumulation of atomic steps in other areas of the top surface 31, and specifically in the accumulation areas 112. Indeed, as better described before in the present description, the accumulation areas 112 can be intended as the atomic steps accumulated on an area of the top surface 31.

It should also be noted that the slow etching step is slow enough to allow for mainly a removal of only atoms at accumulation areas 112, and specifically at atomic steps, i.e., of atoms which are loosely bonded to the SiC surface. Preferably, it will not induce substantial removal of atoms laying on the step-free areas 111, and specifically on the surface terraces, corresponding to atoms belonging to the crystal planes, which are more strongly bonded to the surface.

In more detail, the slow etching process allows to locally dissolve the at least one epitaxial layer 3 along the crystal basal planes 200. In case of the plurality of the epitaxial layers 3, the slow etching process allow to locally dissolve the top most epitaxial layer 3A. In fact, each resulting step-free area 111 corresponds to a respective cavity defined on the top surface 31 and having a bottom surface 111a arranged along the crystal basal planes 200. The bottom surface 111a of each step-free area 111 corresponds, at least partially, to a respective SiO2/SiC interface surface 71 of a respective inversion channel region 7.

It is clear that the process object of the disclosure is also applicable to transistors in order to obtain step-free areas 111 and accumulation areas 112 corresponding to only a fraction of the total number of inversion channel regions 7 and source regions 51, respectively, yet having the same advantages as the process applied on the total number of inversion channel regions 7 and source region 51.

After forming the step-free areas 111, the process comprises the step of fully removing the masking layer 121.

After fully removing the masking layer 121, the process comprises the step of performing standard microfabrication technique. Namely, the process comprises the steps of forming a drain 4, gates, sources 5 and, also preferably, oxide layers 8.

It should be noted that, during the step of performing standard microfabrication techniques, each step-free area 111 will be covered, at least partially, with oxide.

It should be noted that, after the step of performing the standard microfabrication techniques, each resulting inversion channel region 7 of the power transistor 1, incorporated in the semiconductor device produced, is inclined with respect to the top surface 31 by an inclination angle α. Said inclination angle α ranges from 1 to 5°, preferably ranges from 3.5° and 4.5°, most preferably is equal to 4°.

In the following paragraphs three different embodiment of the process for producing a semiconductor device described will be disclosed.

### First Process for Producing a Semiconductor Device

By implementing the first process is possible to produce a semiconductor device 20 incorporating the power transistor 1 described. In particular, the power transistor 1 obtained by implementing the first process is a MOSFET.

The first process comprises the step of providing a support layer 2, in the form of a Silicon Carbide substrate, and forming at least one epitaxial layer 3 having a top surface 31, on top of the support layer 2. Preferably the at least one epitaxial layer 3 is an homoepitaxial layer. The at least one epitaxial layer 3 comprises first implanted regions 32, having opposite doping type as compared to the at least one epitaxial layer 3, and second implanted regions 33, having the same doping type of the at least one epitaxial layer 3. It should be noted that the first 32 and the second implanted regions 33 are formed through implantation processes.

The top surface 31 is initially composed by uncontrolled distribution of steps and terraces due to the misorientation of the support layer 2 made of Silicon Carbide.

According to the first process, the resulting support layer 2 is a highly doped n⁺ layer, while the at least one epitaxial layer 3 is a n doped layer.

Still according to the first process, preferably, the step of forming at least one epitaxial layer 3 comprises forming a lower epitaxial layer 3B and a top most epitaxial layer 3A. Preferably, the lower epitaxial layer 3B has the same doping type of the support layer 2 and the top most epitaxial layer 3A is a n doped layer. More preferably, the lower epitaxial layer 3B is less doped with respect to the support layer 2.

According to the first process, the masking layer 121 is a SiO₂ layer. Therefore, the first process comprises the step of depositing a SiO₂ layer on the top surface 31.

Then, the first process comprises the step of removing the SiO₂ layer in specific areas of the top surface 31 by means of standard lithographic and etching steps. These specific areas, wherein the SiO₂ layer is removed, corresponds, at least partially, to the inversion channel regions 7 of the power transistor 1 to be fabricated.

Afterwards, the first process comprises a slow etching step that allows for the generations of step-free areas 111, where steps are removed, and accumulation areas 112, where the steps will accumulate. Step-free areas 111 corresponds to the specific areas where the SiO₂ layer has been removed in the preceding step.

According to the first process, the slow etching steps is performed in C12, or other chlorine-based environment, at 1 atm and at a temperature above 800 °C, to selectively etch/dissolve loosely bonded Silicon and Carbon atoms at the surface steps.

Then, the first process comprises the step of fully removing the SiO₂ layer by standard wet etching processes.

After fully removing the SiO₂ layer, the first process comprises the step of realizing oxide layers 8, sources 5, gates and a drain 4 by means of standard microfabrication processes.

It can be appreciated that, with the first process described, all inversion channel regions 7 will be located in step-free areas 111.

Therefore, the power transistor 1 obtained by implementing the first process can have all elements of standard vertical Silicon Carbide power transistor with the benefit of the complete removal of any step from the inversion channel regions 7 with consequent improvement of the fabricated devices.

### Second Process for Producing a Semiconductor Device

By implementing the second process, it is possible to realize a semiconductor device incorporating the power transistor 1 described. In particular, the power transistor 1 obtained by implementing the second process is a MOSFET.

Instead of depositing a SiO₂ layer on the top surface 31, as in the first process, according to the second process the masking layer 121 is a C-based polymer layer.

Therefore, after the steps of providing a support layer 2 and forming on top of the support layer 2 at least one epitaxial layer 3, the second process comprises the step of depositing a C-based polymer layer on the top surface 31.

After depositing the C-based polymer layer, the second process comprises performing a lithographic step to open the C-based polymer layer in specific areas corresponding, at least partially, to the inversion channels regions 7 of the power transistor 1 to be fabricated.

Then, before performing the slow etching process, the second process comprises the step of performing a low temperature (<1300 °C) annealing step in Argon, or other inert environments, to convert the C-based polymer to amorphous carbon (aC), by removing hydrogen and oxygen atoms from the polymer.

After the low temperature annealing step, the second process comprises a slow etching step that allows for the generations of step-free areas 111, where steps are removed, and accumulation areas 112, where the atomic steps will accumulate. Step-free areas 111 corresponds to the specific areas where the aC layer has been removed in the preceding step. Preferably, the slow etching step of the second process is performed in Argon or forming gas, or other hydrogen-based environments, at temperature above 1100 °C.

Afterward, the second process comprises the step of removing the aC layer and continuing with standard microfabrication processes as for the first process.

It should be noted that the second process differs from the first process only for the specific type of masking layer 121 and for the associated step for generating the step-free areas 111 and the accumulation areas 112.

### Third Process for Producing a Semiconductor Device

The power transistor 1 obtained by implementing the third process is a Silicon Carbide insulated gate bipolar transistor (IGBT).

According to the third process the support layer 2 is a highly doped n⁺ layer.

Still according to the third process, the step of forming on top of the support layer 2 at least one epitaxial layer 3 comprises forming a lower epitaxial layer 3B on top of the support layer 2.

Preferably, according to the third process, the step of forming on top of the support layer 2 at least one epitaxial layer 3 comprises forming an intermediate epitaxial layer on top of the lower epitaxial layer 3B.

Then, according to the third process, the step of forming on top of the support layer 2 at least one epitaxial layer 3 comprises forming a top most epitaxial layer 3A on top of the lower epitaxial layer 3B or, preferably, on top of the intermediate epitaxial layer.

According to the third process, the lower epitaxial layer 3B is a p⁺ doped layer and will act both as a back Ohmic contact “enhancer” as well as “minority carriers injector” to reduce the RON resistance of the power device.

In case of the intermediate layer, the lower epitaxial layer 3B has the same doping type of the support layer 2 and preferably, the lower epitaxial layer 3B is less doped than the support layer 2. Still in case of the intermediate layer, said intermediate layer is a p⁺ doped layer, acting both as a back Ohmic contact “enhancer” as well as “minority carriers injector”.

According to the third process, the top most epitaxial layer 3A is a n⁻ doped layer.

After having obtained the top most epitaxial layer 3A, the steps of the third process correspond substantially to the one of the first or of the second process.

It should be noted that, before the step of forming a drain 4, the third process comprises the step of removing at least a portion of the support layer 2, so that the drain 4 can directly contacts at least a portion of the lower epitaxial layer 3A. An example of a method for removing at least a portion of the support layer 2 so that the drain 4 can directly contacts at least a portion of the lower epitaxial layer 3A is described in the European patent EP3823008A1, which is to be intended fully incorporated herein.

1. A power transistor for a semiconductor device, comprising:
a support layer made of Silicon Carbide and having a bottom surface:
at least one epitaxial layer grown on top of the support layer and having a top surface opposite to the bottom surface of the support layer with respect to a first direction;
a drain arranged at least partially on the bottom surface of the support layer;
a plurality of gates arranged on the top surface and being spaced apart from each other along a second direction transverse to said first direction;
a plurality of sources arranged on the top surface, each source being interposed between a couple of gates;
a plurality of inversion channel regions being configured to transport charges and generated within the thickness of the at least one epitaxial layer,
wherein
each inversion channel region is inclined with respect to the top surface by an inclination angle substantially equal to the inclination angle of the crystal basal planes, said inclination angle ranging from 1° to 5°, and
each inversion channel region comprises a step-free area and it is devoid of accumulation areas.

2. The power transistor according to claim 1, wherein each source comprises a respective source region, the accumulation areas being arranged at the source region of each source.

3. The power transistor according to claim 2, wherein the top surface comprising terraces and atomic steps.

4. The power transistor according to claim 1, wherein the inclination angle of each inversion channel region ranges from 3.5° to 4.5°, preferably being equal to 4°.

5. The power transistor according to claim 1, comprising:
a plurality of first implanted regions being formed in the thickness of the at least one epitaxial layer; each source being arranged on the top surface above a respective first implanted region.

6. The power transistor according to claim 5, comprising a plurality of second implanted regions, each second implanted region being formed at least partially inside a respective first implanted region.

7. The power transistor according to claim 1, comprising a plurality of oxide layers arranged on the top surface, each oxide layer being placed between a couple of sources, each gate being arranged on top of a respective oxide layer, each inversion channel region being configured to be generated below and in contact with a respective oxide layer.

8. The power transistor according to claim 1, wherein the thickness of the at least one epitaxial layer along the first direction is smaller than the thickness of the support layer along said first direction.

9. A process for producing a semiconductor device incorporating a power transistor, said process comprising the following steps:
providing a support layer made of Silicon Carbide;
forming on top of the support layer at least one epitaxial layer having a top surface;
depositing a masking layer on the top surface;
removing the masking layer in specific areas of the top surface of the at least one epitaxial layer, the specific areas corresponding, at least partially, to the inversion channel regions of the power transistor to be fabricated;
performing a slow etching process allowing for the generations of step-free areas, located at the specific areas of the top surface, and accumulation areas, adjacent to the step-free areas, the step-free areas corresponding, at least partially, to inversion channel regions of the power transistor to be fabricated, the accumulation areas corresponding, at least partially, to the source regions of sources of the power transistor to be fabricated, the slow etching process allowing for removal of only atoms at the accumulation areas;
fully removing the masking layer;
performing standard microfabrication technique.

10. A process according to claim 9, wherein after the step of performing the standard microfabrication technique, each resulting inversion channel region of the power transistor, incorporated in the semiconductor device produced, is inclined with respect to the top surface by an inclination angle, said inclination angle ranging from 1° to 5°, preferably ranging from 3.5° and 4.5°, most preferably equal to 4°.

11. A process according to claim 9, wherein:
the masking layer is a SiO2 layer; and
the slow etching process is performed in C12 at 1 atm and at a temperature above 800 °C.

12. A process according to claim 9, wherein:
the masking layer is a C-based polymer layer;
before performing the slow etching process, the process comprises performing a low temperature annealing step in Argon to convert the C-based polymer to amorphous carbon, by removing hydrogen and oxygen atoms from the polymer; and
the slow etching process is performed in Argon or forming gas, or equivalent hydrogen-based environments, at a temperature above 1100 °C.

13. A process according to claim 10, wherein the step of forming on top of the support layer at least one epitaxial layer comprises:
forming a lower epitaxial layer on top of the support layer, said lower epitaxial layer being a p+ doped layer;
forming a top most epitaxial layer on top of the lower epitaxial layer, said top most epitaxial layer being a n− doped layer.
